(19) United States
(12) Patent Application Publication
(10) Pub. No.: US 2025/0190647 A1
(43) Pub. Date: Jun. 12, 2025

(54) LOW OVERHEAD OPERATING SYSTEM FOR SIMULATION OF EMBEDDED SYSTEM

(71) Applicant: Synopsys, Inc., Sunnyvale, CA (US)

(72) Inventor: Nicolas Amringer, Erwitte (DE)

(21) Appl. No.: 18/444,248

(22) Filed: Feb. 16, 2024

Related U.S. Application Data
(60) Provisional application No. 63/540,856, filed on Sep. 27, 2023.

(51) Int. Cl. G06F 30/20; G06F 11/36

(52) U.S. Cl. CPC G06F 30/20; G06F 11/3608

(57) ABSTRACT

A method includes: receiving a software system under test including a software application; determining one or more operating system application programming interfaces invoked by the software system under test; compiling, by a processing device, a simulated operating system including a reduced interface layer providing services associated with the one or more operating system application programming interfaces that are invoked by the software system under test, the services including a virtual timer; and outputting the simulated operating system configured to execute the software system under test.

### TECHNICAL FIELD

The present disclosure relates to testing and verifying the operation of software programs targeting embedded systems.

### BACKGROUND

Many electronic devices have integrated computer systems, frequently referred to as embedded systems. For example, Internet-of-Things (IoT) devices typically include integrated electronic microcontrollers. In addition, modern automobiles and other types of vehicles include at least one electronic control unit (ECU) to control features such as power steering, brakes, infotainment, and an advanced driver-assistance system (ADAS). Advances in computing technology, such as decreases in cost and power consumption and increases in computing performance and memory density, have enabled these electronic devices to provide enhanced features implemented using software running on these integrated computer systems.

The above information disclosed in this Background section is only for enhancement of understanding of the present disclosure, and therefore it may contain information that does not form the prior art that is already known to a person of ordinary skill in the art.

### BRIEF DESCRIPTION OF THE DRAWINGS

The disclosure will be understood more fully from the detailed description given below and from the accompanying figures of embodiments of the disclosure. The figures are used to provide knowledge and understanding of embodiments of the disclosure and do not limit the scope of the disclosure to these specific embodiments. Furthermore, the figures are not necessarily drawn to scale.

FIG. 1 is a schematic diagram of a portion of a verification system using a low-overhead unikernel supporting a system under test including middleware and applications, according to one embodiment of the present disclosure.

FIG. 2A is a block diagram depicting components of a unikernel, according to some embodiments of the present disclosure.

FIG. 2B is a signal diagram depicting communications between a system under test, a verification system, and a unikernel, according to embodiments of the present disclosure.

FIG. 3 is a flowchart depicting a method for building a unikernel for verification of a system under test, according to one embodiment of the present disclosure.

FIG. 4 is an example of a vehicle electronic control unit (ECU) development and verification platform including a simulation of the operation of a system under test of an ECU using a low-overhead unikernel, according to one embodiment of the present disclosure.

FIG. 5 is a flowchart depicting a method for performing verification of a software system under test, according to one embodiment of the present disclosure.

FIG. 6 depicts a diagram of an example computer system in which embodiments of the present disclosure may operate.

### DETAILED DESCRIPTION

Aspects of the present disclosure relate to a low overhead operating system for simulation of embedded systems.

Computer systems that are integrated into devices such as vehicles, household appliances, industrial tools (e.g., robots), and the like may be referred to as embedded systems. These embedded systems allow the devices to provide functionality implemented as software programs, rather than using special-purpose electronic hardware or mechanical devices. For example, in road vehicles, software running on an electronic control unit (ECU) provides electronic stability control (ESC) or dynamic stability control (DSC), which monitors the loss of steering control and automatically applies the brakes to help steer the vehicle. In more advanced vehicles, the ECU may include additional functionality relating to an advanced driver-assistance system (ADAS), such as receiving sensor data (e.g., radar information) to track the distances to objects around the vehicle and automatically controlling the vehicle (e.g., accelerating, braking, and steering) in response to these data (e.g., maintaining a set distance from another vehicle or braking or swerving to avoid collisions). As another example, robotics systems in manufacturing environments may include embedded processors to dynamically control the operations of those robots based on their environments, such as analyzing workpieces and controlling a robot arm to perform a task based on the analysis.

The complex functions performed by these integrated controllers may be expensive to implement using specially designed integrated circuits but may be comparatively economical to implement using software programs running on digital processors, due in part to the falling cost and increasing computational capabilities of these processors. As the role of the software running on embedded systems (such as ECUs of a vehicle) increases, an increasing portion of the engineering effort of manufactured products is invested in the software running on the embedded processors.

For example, the term software defined vehicle (SDV) has come into use to refer to the large proportion of engineering effort expended on the software component of some vehicles (e.g., autonomous automobiles). In a SDV approach, the functions of many disparate ECUs performing specific functions for different parts of the vehicle are consolidated into a smaller number of centralized ECUs. The centralized ECUs generally have more powerful processors (e.g., microprocessors) rather than embedded microcontrollers. The more powerful microprocessors also provide sufficient headroom for these centralized ECUs to run operating systems to support software applications to implement advanced features such as ADAS, in-vehicle entertainment, and the like. The use of operating systems that follow standards (e.g., portable operating system interface or POSIX®) allows engineers to focus their efforts on building differentiating features in their specialized software.

For example, an infotainment system of a vehicle (e.g., to perform climate control, provide navigation, and play audio content) may be implemented as one or more software applications running on a software platform that provides application programming interfaces (APIs) for displaying graphics on an in-cabin display device, receiving user input through corresponding in-cabin controls (e.g., a touchscreen), communicating with user devices (e.g., a smartphone), and receiving sensor data from the vehicle. The software platform may include an operating system such as Linux® or Android® running on a microprocessor of an ECU. Building applications on a software platform saves engineering time, as engineers can use services provided by the operating system (e.g., timers, device drivers, data storage interfaces (e.g., file systems), communications protocols such as Bluetooth® and cellular network protocols, and the like) and third-party application software (e.g., databases, audio and video codecs, graphical user interface libraries, and the like). One example of operating system standards is portable operating system interface (POSIX®), which enables application compatibility across different Unix-like operating systems. The POSIX® standard includes definitions of certain application programming interfaces (APIs) for functionality such as threading and network communication. Various operating systems such as Linux®, FreeBSD®, macOS®, and the like exhibit various levels of compliance with the POSIX® standard.

Verification of software and electronic devices may include checking that a device produces the expected outputs in response to specific inputs. The product being verified by be referred to as a device under test (DUT) or system under test (SUT). For example, when verifying the operation of an ECU for providing electronic stability control, inputs from sensors (e.g., accelerometers, steering wheel position, brake position, and the like) may be provided to the ECU and the output of the ECU would be monitored to ensure that it provided expected outputs to control the brakes of the wheels.

While verification can be performed on fabricated, real-world prototypes (e.g., a prototype ECU installed in a vehicle), this approach can be costly and impractical for the development process, especially in relation to functionality that does not rely heavily on the vehicle itself (e.g., audio playback) or where collision avoidance systems are being tested (e.g., due to the risk of physical damage). A more economical, but sometimes less accurate approach is to perform verification within a simulation environment executed by a simulator backend of a verification system (which may include a computer system). A simulation environment also provides benefits such as increasing control over the environment from which the SUT receives inputs and allowing easier inspection of the state of the SUT during the tests (e.g., pausing the simulation to inspect the values of variables).

In many cases, application software that is being tested or verified uses only a small fraction of the functionality provided by an operating system. For example, applications that adhere to the automotive open system architecture (AUTOSAR®) Adaptive standard are only allowed to call APIs that are part of the POSIX® portable system environment (PSE) 51 profile, and PSE51 does not require the presence of a file system. Furthermore, running the full production operating system (e.g., that would be deployed in the device containing the embedded system) may impose a high overhead on the verification system. This overhead reduces the performance (e.g., speed) of the verification system, thereby increasing costs and lengthening turnaround time for generating feedback for the engineer (e.g., generating results of the verification tests). In addition, some operating systems, such as Linux®, are licensed under terms that are unfavorable to organizations that would prefer to keep their software products proprietary (e.g., variants of the GNU General Public License or GNU GPL).

Therefore, aspects of embodiments of the present disclosure relate to a low-overhead operating system for simulation of embedded systems, which may be used to perform verification of software applications and middleware. Operating systems or virtualized operating system environments according to embodiments of the present disclosure are tailored to provide only the functionality (e.g., APIs) used by the software applications and middleware under test (or system under test). The operating system (or virtualized operating system) provides functionality and drivers for interacting with a simulator backend that provides environmental information (e.g., sensor inputs) and that may also provide a simulated environment for the system under test to interact with, including providing outputs from the simulator backend to the applications through the operating system. Using a simulation backend and operating system according to embodiments of the present disclosure has reduced overhead compared to running a full operating system and provides a high degree of control over the simulation process.

Technical advantages of the present disclosure include, but are not limited to, reducing computational overhead of verifying software applications of a system under test. In this case, the provision of a specialized simulated operating system that provides only the minimal set of interfaces and functionalities (e.g., a file system, an Ethernet stack, drivers, and the like) needed to validate and verify the software running on the operating system has advantages in terms of operating system image footprint (e.g., memory usage) and faster boot and simulation times (reduced resource consumption compared to a full operating system). This enables better scalability and shorter feedback loops, but also creates less overhead, such as when the simulated operating system is stored in a version control system (e.g., Git® or Mercurial) or exchanged between different parties (e.g., suppliers) as part of the software development process. This improves the performance of the simulation, which enables more tests to be run within a time budget for performing verification, thereby leading to higher quality end-products. Higher performance and lower cost validation and verification (V&V) also enables continuous integration or continuous validation and verification development processes, where changes to the software are tested, validated, and verified immediately during the engineering process, rather than waiting for batch testing. In addition, running the software application and middleware in a simulation environment which enables a high degree of control of the environment, which allows embodiments to test the applications of the SUT under many different operating conditions (e.g., including out-of-memory conditions, data loss conditions, hardware failure conditions, and the like).

One approach to provide a simulated POSIX®-based OS is to execute a modified Linux® in a virtual machine (VM) on top of a hypervisor. Using a POSIX®-based OS, which offers a full POSIX® interface like Linux®, is often not required, especially in early development phases where only specific parts of the ECU software stack need to be validated and verified (e.g., a perception algorithm that receives input from a sensor as part of an ADAS ECU). This approach leads to scalability issues and longer feedback loops e.g., in regression test use cases where a larger number of tests must be executed. One prominent example is the validation and verification of a driver assistance function in different traffic scenarios. Additionally, the modification of a copyleft (e.g., GPL-licensed) open-source POSIX®-based OS like Linux® may create derivative works that might also need to be open-sourced, which may make it difficult to create proprietary software because any source code change may need to be disclosed in order to comply with the GPL.

An alternative approach where an unmodified POSIX® compatible host operating system (e.g., Linux®) is used to validate and verify applications/middleware may result in reduced control over the verification environment due to the lack of determinism, lack of virtual hardware (HW) models (e.g., a virtual timer), lack of testing functionalities (e.g., support for failure injection), and lack of automotive standards support, for example AUTOSAR® diagnostic log and trace (DLT). In addition, differences in implementation details between different POSIX®-compatible operating systems (e.g., Linux® versus QNX®), such as with respect to non-standard functionality (e.g., APIs) provided by one operating system and another and such as with respect to undefined behavior in the POSIX® standard, may lead to test results that are different from production. In general, POSIX® API calls can also be intercepted with different mechanisms (e.g., a Linux® command ptrace on a Linux® host OS) for simulation purposes, but these mechanisms are slower and require the creation of a simulation POSIX®-based OS e.g., to maintain the internal state between multiple POSIX® API function calls (see e.g., socket calls such as the socket( ) function to create an endpoint for communication, the connect( ) function to initiate a connection on a socket, and the send( ) function to send a message on a socket).

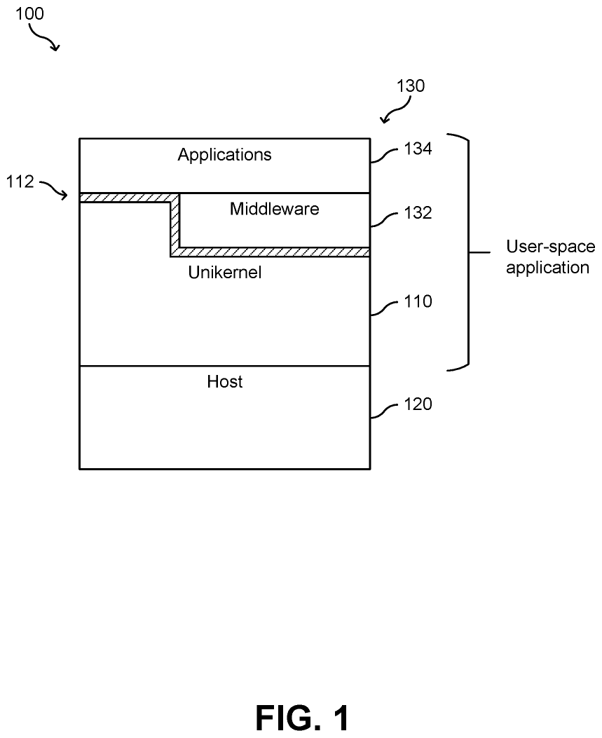

The present disclosure relates to a low-overhead (e.g., resource-optimized) POSIX®-based operating system. FIG. 1 is a schematic diagram of a portion of a verification system 100 using a low-overhead unikernel 110 running on a host operating system kernel 120 (e.g., executed by a computer system) supporting a system under test 130 including middleware 132 and applications 134, according to one embodiment of the present disclosure. The following sections motivate the use and benefits of a unikernel and describes how it is integrated into a verification system.

Unikernel approach: unikernels and containers are both technologies that are used for application deployment and execution (e.g., in cloud computing environments) but there are key differences in relation to this work. Containers are more generic and have a larger footprint than unikernels. Instead of providing their own operating system kernel (as in the case of a full virtual machine), containers use the underlying host operating system kernel. A unikernel is a computer program configured to be executed by a processing device, where the unikernel program is linked with operating system code that the unikernel uses. For example, the unikernel is built with a compiler that identifies the operating system services that an application program uses and links the unikernel program with the corresponding operating system services such that the application program running on the unikernel can access those operating system services.

Compared to containers, unikernels are highly specialized and are customized to contain only the components of the kernel that are required to run a specific application (e.g., only to include code to support the portions of the POSIX® API that are accessed by the application). In other words, the unikernel 110 provides a desired API (e.g., minimal API) or a desired POSIX® interface (e.g., a minimal POSIX® interface) or reduced interface layer 112, as customized to meet the needs of the specific software system under test 130, including middleware 132 and applications 134, that will run on the unikernel 110. The middleware 132 includes software instructions performed by a processing device, where the software instructions provide, for example, communication and data management between the applications 134 and the unikernel 110. The applications 134 refer to one or more application programs performing a desired computer function by a processing device. This, in turn, means that a unikernel is fast to build (or compile) and has an extremely low memory footprint, which improves the performance of simulations of ECUs and other embedded systems, where low model footprint, speed, scalability, and fast turnaround times improve the development process for developing the system under test 130 (e.g., the middleware 132 and applications 134), including verification and validation of the operation of the system under test 130. Furthermore, the unikernel, which may also be referred to herein as a simulation operating system, is independent from the host operating system and can be customized according to concrete requirements of the software system under test 130, such as by customizing the unikernel to behave in a manner that matches the behavior of a production operating system that the software application will run on in production (e.g., with respect to behavior that is undefined in the POSIX® standard and implementing special-purpose application programming interfaces).

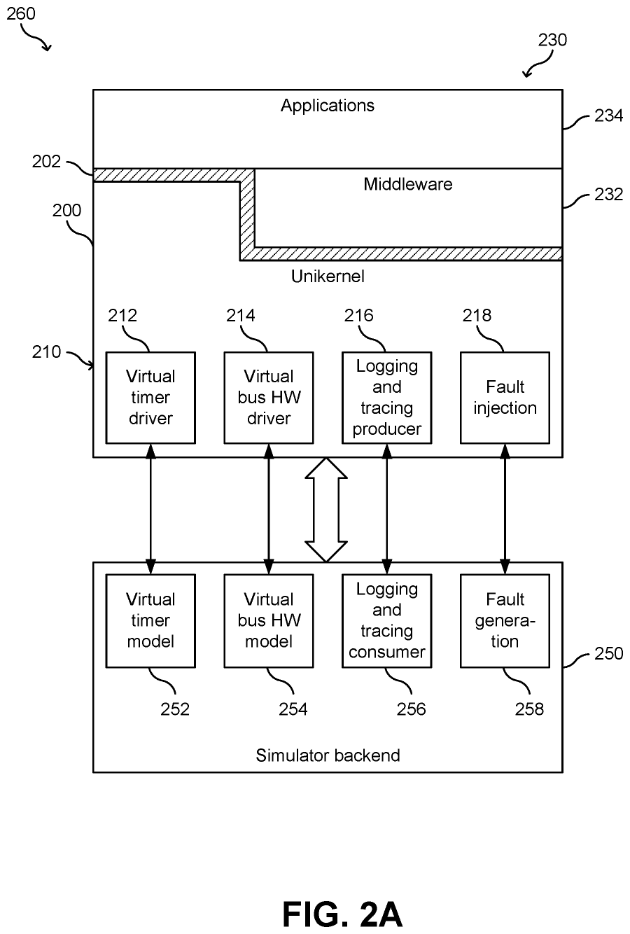

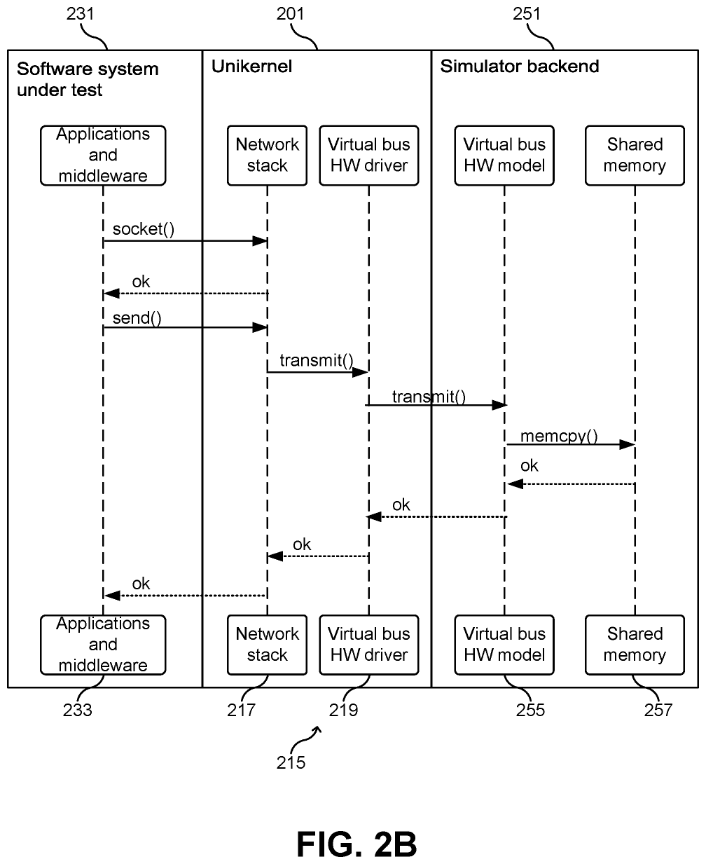

FIG. 2A is a block diagram depicting components of a unikernel 200, according to some embodiments of the present disclosure. The unikernel 200 implements only the portions of a full application programming interface provided by an operating system (e.g., POSIX® API) that are required by a system under test 230, where the exposed implemented portion of the API is presented as a minimal API or reduced interface layer 202. The system under test 230 may include middleware 232 and/or applications 234 developed by a user for implementing an embedded system (e.g., an ECU for a vehicle), and therefore the portions of the full API that are implemented in a unikernel 200 according to embodiments of the present disclosure are customized based on the application (e.g., by static analysis to track the operating system API calls made by the system under test 230 during compilation or build and building in only the portions that are needed to implement those identified OS API calls during compilation and/or linking of the unikernel).

The unikernel 200 communicates with a simulator backend 250, which manages other parts of the verification of the system under test 230. For example, the simulator backend 250 may include or manage a simulation environment that provides test inputs to be supplied to the system under test 230 through the unikernel 200, receives outputs generated by the system under test 230, simulates the effect of the outputs from the system under test 230 on some environment, and may present updated inputs to the system under test 230. The simulator backend 250 may include one or more software applications running on the same computer system as the unikernel 200 and the system under test 230 and/or may further include one or more software applications running on other computer systems (e.g., in communication with the computer system running the unikernel 200 and the system under test 230 over a computer network connection or other communication link). The unikernel 200 and the simulator backend 250 operate within the context of a verification system 260 which, as noted above, may be implemented using one or more computers, each including processing circuits or processing devices such as central processing units (CPUs) and graphics processing units (GPUs).

For example, in the case of an ADAS system as the system under test 230, the simulator backend 250 may maintain or interact with a simulated three-dimensional (3-D) model of a driving environment (e.g., using a three-dimensional (3-D) physics engine) including a simulated vehicle. The inputs to the system under test 230 may include image data captured by virtual cameras of the simulated environment around the simulated vehicle, and the outputs from the system under test 230 may include controls that steer and/or control the acceleration (throttle) and deceleration (brakes) of the simulated vehicle. Updated input data from the simulation environment in response to the controls may then supplied back to the system under test 230.

A unikernel 200 according to embodiments of the present disclosure further includes unikernel components 210 that are specific to its use in verification of a system under test 230 running on the unikernel 200. In the embodiment shown in FIG. 2A, these unikernel components 210 include drivers for interfacing with virtual hardware simulated by a simulator backend, such as a virtual timer driver 212, virtual bus hardware drivers 214, logging and tracing producer 216, and fault injection 218, which will be described in more detail below.

Generally, test cases in a verification system should be reproducible-any given test should pass or fail when executed on a given version of the system under test, regardless of the current time at which the test is run and independently of the underlying host machine (e.g., in the case of a simulated three-dimensional or 3-D environment, a test of operation of the detection algorithms under low-light conditions should always generate simulated low-light conditions, whether the current real-world time is day or night, as additional examples executed procedures, bus and network data packets, log messages, and the like produce the same results or provide the same data independently of the current time and independently of the execution speed of the underlying host computer). This increases confidence that changes made to the system under test have resolved the problem, rather than finding that the problem has gone away due to random external variation.

To enable repeatable test execution, aspects of embodiments of the present disclosure relate to controlling the unikernel 200 to run deterministically on a virtual time basis that is independent of real time (e.g., the wall-clock time), where the virtual time is controlled by a simulator backend running a simulation of an environment for testing the software system under test. This allows greater control over the environment presented to the software system under test because the simulator can fully control the time that observable by the software system under test, instead of being subjected to a timer of a host computer system that runs based on real time (e.g., wall time). This virtual time may be faster or slower than real time (e.g., depending on the quality or level of detail of the simulated environment and performance of the simulator backend, such as the capabilities of the hardware running the simulator and the efficiency of the simulation software). In some embodiments, an unikernel time mechanism is replaced with a virtual timer driver 212 (or frontend virtual timer) that provides an interface for a virtual time provided from a simulator backend virtual timer model 252 of the simulator backend 250. In more detail, in some embodiments the simulator backend provides a virtual timer hardware model and a mechanism to increment the virtual time in an event-discrete fashion, such that the simulated virtual timer driver 212 in the unikernel 200 that is accessed by the middleware 232 and the applications 234 is synchronized with the virtual time in the environment simulated by the simulator backend 250.

As another example of a unikernel component 210 specific to use in verification of a system under test 230 in accordance with embodiment of the present disclosure is a virtual bus hardware driver component 214. For example, to enable verification of a system under test 230 that interacts with specialized communication buses, virtual bus hardware driver 214 is integrated with the unikernel 200 and communicate with virtual bus hardware models 254. These virtual bus hardware models are provided by the simulator backend 250 which allows the simulator backend to implement virtual bus communications (e.g., providing freedom from the bandwidth limitations of a real bus). In the case where the system under test 230 is an application for an automotive ECU, examples of automotive bus systems are automotive Ethernet and Controller Area Network (CAN). However, embodiments of the present disclosure are not limited thereto and may include other types of virtual bus hardware models for other communications, such as virtual network stacks (e.g., for cellular, Wi-Fi, Bluetooth®, and other network connections that use, for example, transmission control protocol/internet protocol (TCP/IP) communication stacks or user datagram protocol (UDP) network functionality), proprietary network protocols specific to a use case, local communication bus protocols such as universal serial bus (USB), peripheral component interconnect express (PCIe), and the like.

In contrast to a hypervisor approach where a virtualized operating system runs on a hypervisor and in contrast to a containerized approach where the virtualized operating system uses an underlying host kernel, the virtual bus hardware driver 214 according to embodiments of the present disclosure does not need to interact with the host operating system network stack (e.g., provided by the host kernel). Instead, socket communication is routed from the POSIX® APIs through a network stack (e.g., implemented in a virtual bus HW driver 214 for a network stack in communication with a virtual bus HW model 254) that runs within the unikernel 200 to the driver interacting directly with a virtual bus hardware model 254 provided by the simulator backend 250 which uses shared memory to communicate with other components of the verification system, such as simulations of other ECUs under test (not necessarily simulations of other ECUs running on POSIX® operating systems), which may be controlled by the same simulator backend 250 or other simulator backends, in contrast to communicating with bus hardware exposed by a host operating system which is not under the control of the simulator backend 250 and which therefore may exhibit unpredictable and uncontrolled behavior. Using a virtual bus HW driver 214 in communication with a virtual bus HW model 254 not only increases performance, but also increases control over the simulation environment (e.g., the environment exposed to the system under test 230) because it avoids interference with the host operating system (e.g., the network stack), which may have influence on the reproducibility of simulation results. In addition, the virtual bus hardware driver 214 increases control by allowing the simulator backend 250 to intercept data transmitted to the virtual bus hardware model 254 by the system under test 230 through the virtual bus hardware driver 214 of the unikernel 200, thereby allowing the simulator backend 250 to directly interact with and respond to the data, as discussed in more detail below. This allows the simulator backend to control the data that is presented to the software system under test by the virtual bus HW model 254 via the virtual bus HW driver 214 to a degree that would not be possible if, for example, the software system under test were communicating through a non-virtualized bus driver to communicate with a communication bus exposed by a host computer system.

FIG. 2B is a signal diagram depicting communications between a system under test, a simulator backend, and a unikernel according to embodiments of the present disclosure. The communications occur during runtime of the system under test running on a unikernel in accordance with embodiments of the present disclosure during a verification process of the system under test (e.g., testing the operation of the system under test). The example of FIG. 2B depicts virtual Ethernet communication initiated by a software system under test 231 (including applications and middleware 233) using POSIX® APIs provided by the virtual bus hardware 215 of the unikernel 201, where the virtual bus hardware 215 may include a network stack 217 (e.g., implementing layers of a networking stack such as TCP/IP) and a virtual bus hardware driver 219 (e.g., an Ethernet driver in the case of a virtual Ethernet hardware bus). In some embodiments, the virtual bus hardware driver 214 shown in FIG. 2A includes the virtual bus hardware 215 shown in FIG. 2B. The software system under test 231 writes output to the virtual bus hardware 215 (or other operating system services) via the API of the service exposed by the reduced application programming interface provided by the unikernel 202. Instead of routing the network communication through a host network stack (e.g., provided by the underlying host kernel that the unikernel 200 runs on top of), the simulator backend 251 provides a virtual bus hardware model 255 that uses shared memory 257 to communicate with other ECU simulations (e.g., other ECU simulations running on the same computer) by copying data to other portions of memory (as indicated by the memcpy( ) function) or may use the host network stack to communicate with other ECU simulations running on other computers (e.g., by copying data to a memory location to be accessed by the host network stack). Likewise, incoming data to the software system under test passes from the shared memory 257 of the simulator backend 251 through the virtual bus hardware model 255 and into the unikernel 201 through the virtual bus hardware 215 to be read as input to the software system under test 231.

Additionally, this approach does not need elevated privileges on the host computer system (e.g., in the host operating system) and does not require host kernel modifications to run the simulation environment for the system under test 230. Embodiments of the present disclosure enable a system under test 230 to run a unikernel 200 which, in turn, can be executed on a computer system as a user-space program (that is, without elevated privileges, such as administrator privileges). In particular, because the unikernel 200 according to embodiments of the present disclosure integrates the virtual bus hardware driver 214, there is no need to install, for example, a network tap by modifying the underlying host operating system kernel (e.g., in order to intercept the network accesses requested by the system under test 230), which may require elevated privileges (e.g., administrator privileges). In some embodiments, a CAN library (e.g., SocketCAN library) is integrated into the unikernel 200 so that CAN messages can be sent and received to and from the system under test 230 (the applications 234 and middleware 232) without requiring these protocols to be available on the host operating system. Here, the virtual bus HW model 254 of the simulator backend 250 is used to transmit and receive CAN messages sent by and to the simulated system under test 230, where the exchanges of CAN messages can be performed via the shared memory (rather than through an actual or emulated CAN bus), thereby improving the performance of the simulation.

Some aspects of embodiments of the present disclosure relate to logging and tracing producer 216 (or logging and tracing client). This logging and tracing producer 216 may be used, in some embodiments, to support ECU software validation and verification based on automotive standards. For example, to log and trace ECU SW execution according to the AUTOSAR® Diagnostic Log and Trace (DLT) standard some embodiments integrate a DLT daemon (shown in FIG. 2 as logging and tracing producer 216) into the unikernel 200 that communicates with the logging and tracing consumer 256 of the simulator backend 250, which acts as a DLT client (e.g., where the DLT daemon provides traces in a DLT format). The logging and tracing producer 216 may also be used to log and trace the execution of the system under test 230, including the execution of POSIX® API calls and or the internal state by the simulated POSIX® OS, for debugging the applications 234 and the middleware 232. The logging and tracing may further use timestamps from the virtual timer, which improves interpretability of the logs, especially when attempting to reproduce errors by re-running tests, because the timestamps can be kept consistent from run-to-run.

In addition, for validation and verification purposes, it is especially relevant to also simulate certain dynamic error conditions or faults on the POSIX® interface level. Some examples of faults include out of memory, connection reset (e.g., network connection reset), connection timeout (e.g., network connection timeout), and system reboot scenarios. In many circumstances, verification of a system under test 230 includes verifying that these error conditions or faults reported to the application or middleware by an operating system through the POSIX® interface layer are handled safely (e.g., an out of memory condition does not cause an ADAS system to fail catastrophically, but instead where the ADAS system may continue operating normally or where the ADAS system undergoes a graceful degradation that protects the safety of the occupants of the vehicle and the environment around the vehicle). Accordingly, some aspects of embodiments of the present disclosure relate to a fault injection component 218 that is configured to inject faults or report synthetic faults to the system under test 230 through the reduced interface layer 202 of the unikernel 200. For example, the fault injection component 218 may cause a memory allocation call (e.g., malloc or calloc) from the middleware 232 or the applications 234 to return that an out of memory fault has occurred, thereby allowing an engineer to test and verify the response of the application to such a fault. As another example, the fault injection component may cause the virtual bus hardware model 254 or the virtual bus hardware driver 214 to present a connection reset fault to the system under test 230. In some embodiments, the faults are generated or introduced through a fault generation component 258 of the simulator backend 250. In more detail, a particular test of a verification suite may cause the ECU under test to enter a particular state (e.g., a state where the ECU is concurrently playing music while providing driving directions and providing ADAS) and use the fault generation component 258 to inject a fault through the fault injection component 218 of the unikernel 200 such as a system reset (e.g., caused by the perception system detecting an unknown object in the environment) at a time when the ADAS would control the vehicle to take an evasive action to avoid a collision with another vehicle.

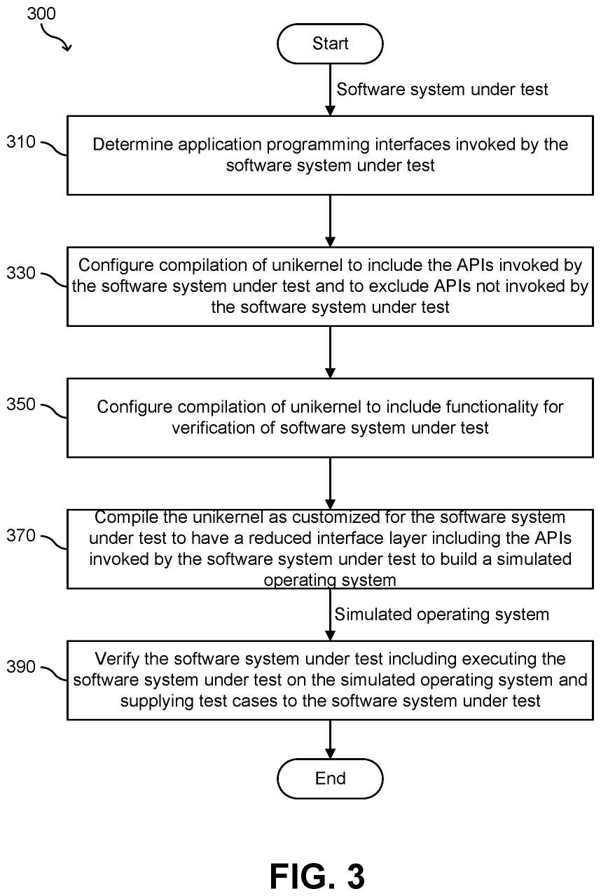

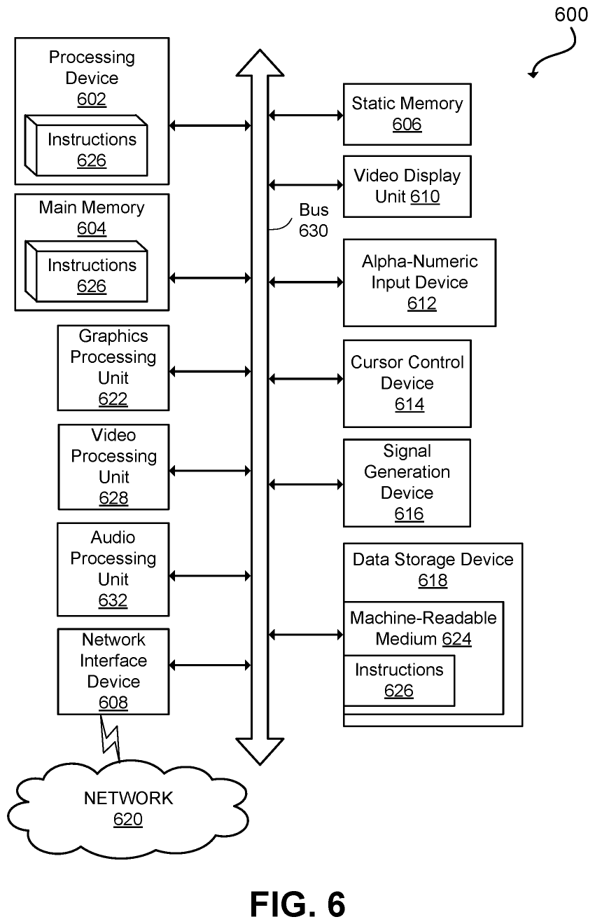

FIG. 3 is a flowchart depicting a method 300 for building a unikernel for verification of a system under test, according to one embodiment of the present disclosure. In various embodiments of the present disclosure, the method may be implemented using one or more computer systems or machines including a processing device such as that described below with respect to FIG. 6. A system under test or software system under test which includes one or more user applications (e.g., applications 234 shown in FIG. 2A) and, in some cases, middleware (e.g., middleware 232 shown in FIG. 2A) is provided to the method 300. In some embodiments of the present disclosure, the building of the unikernel includes compiling a unikernel (e.g., generating object code from one or more source code files) and may further include linking a unikernel (e.g., connecting object code to generate an executable binary file). In various embodiments of the present disclosure, the application and the middleware can be combined with the unikernel using different approaches. One approach is to compile the unikernel (or portions thereof) together with the applications and the middleware. Another approach is to statically link the unikernel (or portions thereof) together with the applications and the middleware. A third approach is to compile and link the application and the middleware separately or independently from the unikernel and then dynamically load and link the application and the middleware to the unikernel at runtime.

At 310, the processing device automatically analyzes the software system under test to determine operating system application programming interfaces (APIs) invoked by the software system under test. For example, in some embodiments, the processing device preforms static analysis of the software system under test to identify or determine invocations of APIs. In the case where the software system under test is provided as source code, then the inclusion of libraries or header files for accessing POSIX® APIs (or other operating system APIs) and/or the invocation of functions or other system calls to access those APIs are detected and the processing device stores a list or other collection of the detected uses of the APIs. (This may include circumstances where portions of the software system under test are implemented using a compiled programming language such as C as well as circumstances where portions of the software system under test are implemented using an interpreted programming language such as Python or JavaScript.) In the case where the software system under test is provided as compiled object code or binary code, then the processing device detects system function invocations from the object code to shared libraries (e.g., libraries provided by the POSIX® API) that would be accessed using dynamic linking during runtime.

At 330, the processing device automatically configures compilation of the unikernel to include code to support for APIs that are invoked by the software system under test (as previously determined at 310 based on analysis of the software system under test). In some embodiments, the processing device further configures the unikernel to exclude code to support for APIs that are not invoked by the software system under test. For example, a system under test that only performs local operations (e.g., a clock application) may not make use of network communication functions and/or file system operations, and therefore code to support a virtual timer driver 212 may be included in the unikernel and code to support virtual bus hardware driver 214 and file systems may be excluded from the unikernel.

At 350, the processing device automatically configures compilation of the unikernel to include functionality for performing verification of the software system under test. This includes, for example, logging and tracing producer 216 and fault injection code 218 described above with respect to FIG. 2A.

At 370, the processing device compiles the unikernel as customized for the software system under test to generate a simulated operating system. In more detail, according to some embodiments, the unikernel is customized by including code and/or linking code to support the APIs that are invoked by the software system under test while excluding code that would otherwise support APIs that are not invoked by the software system under test. The unikernel is further customized to include functionality that is specific to use for simulation for purposes of verification of the software system under test, such that the customized unikernel is a specialized simulated operating system. In some circumstances, depending on the configurability of the unikernel, some relatively small amounts of code supporting APIs that are not invoked by the software system under test may still be included in the compiled unikernel (e.g., because the level of granularity of the configuration of the unikernel does not allow a particular API invoked by the system under test to be supported by the unikernel without also including another API that is not invoked by the system under test).

In some embodiments, the compiling of the unikernel further includes statically linking the system under test and the compiled unikernel to generate a static executable binary file to be executed during verification of the system under test. In some embodiments, the software system under test is dynamically linked with the unikernel at runtime (e.g., when performing verification of the system under test).

At 390, a verification system verifies the software system under test, which includes executing the software system under test on the simulated POSIX® operating system and supplying test cases to the software system under test, as will be described in more detail below.

Experiments using the design according to embodiments of the present disclosure show that unikernel operating system images can be used to simulate a POSIX®-based OS for ECU SW stacks used in the autonomous driving domain.

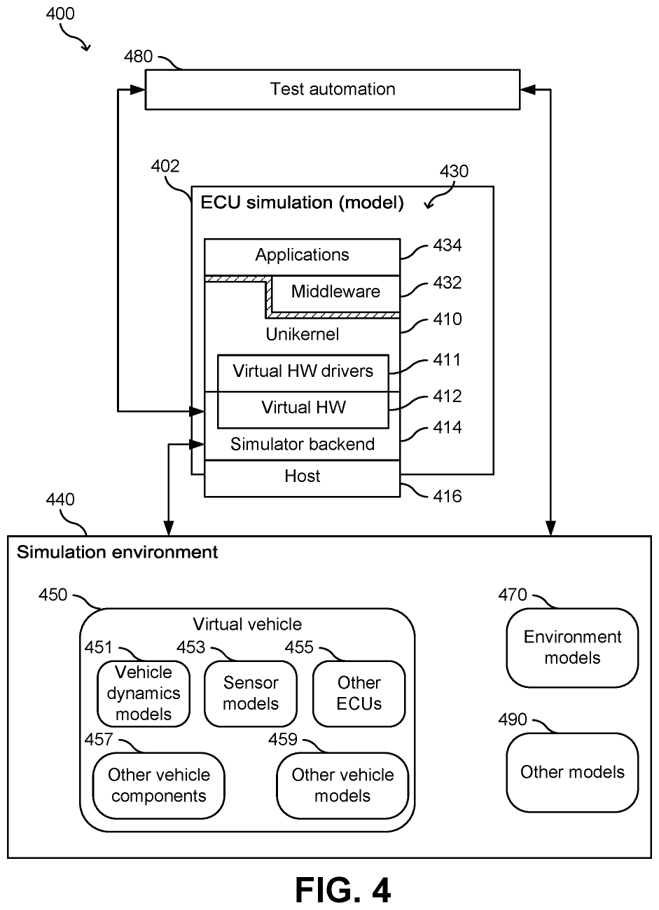

FIG. 4 is an example of a vehicle ECU development and verification platform 400 including a simulation of the operation of a system under test 430, including middleware 432 and applications 434, of a simulated electronic control unit (ECU) 402 using a low-overhead unikernel 410 according to one embodiment of the present disclosure. The unikernel 410 includes virtual hardware (HW) drivers 411 that interact with corresponding virtual hardware (HW) 412 (e.g., virtual network hardware, virtual timer, and the like) provided by the simulator backend 414, which runs (e.g., as application software) on a host kernel 416 running on a computer system.

The simulated ECU 402 communicates over a virtual bus with a simulation environment 440 which, in the example of FIG. 4, includes a virtual vehicle 450, which is simulated in accordance with vehicle dynamics models 451 and sensor models 453 and environment models 470 of the vehicle ECU development and verification platform 400. The simulation environment 440 may further include communications with other ECUs 455, which may be simulated ECUs or real ECUs (e.g., physical hardware devices as would be used in a production vehicle) and may also include communications with other vehicle components 457 such as batteries, thermal systems, and the like (which may also be simulated in software or physical hardware devices). The models included in the virtual vehicle 450 are not limited to the categories described above and may include other vehicle-related models 459, as relevant to testing the software system under test. The environment models 470 provide information regarding the simulated environment around the vehicle, such as traffic, traffic signs, and road objects, and are also part of the simulation environment 440. The simulation environment 440 is not limited to models associated with the virtual vehicle 450 and the environment 470 and may also include other models 490 that may not fit into the above categories. The simulation environment 440 may be implemented in software running on the same host 416 as the simulator backend 414 or may be running on one or more other computer systems separate from the host, where the simulator backend 414 communicates with the simulation environment through, for example, a network connection. A test automation service 480 then drives the tests of the verification process (e.g., a test suite) to test whether the system under test 430 operates in accordance with specifications. The test automation service 480 may, likewise, run on the same host 416 as the simulator backend 414 or may run on different computer systems and communicate with the simulator backend 414 and the simulation environment 440 to present test cases of the test suite to the software system under test 430 during the verification process.

In more detail, the test automation service 480 may present a test case to a software system under test 430 by configuring the simulation environment 440 and the simulator backend 414 to present inputs to the software system under test 430 and to update the state of the simulation environment 440 based on outputs of the software system under test.

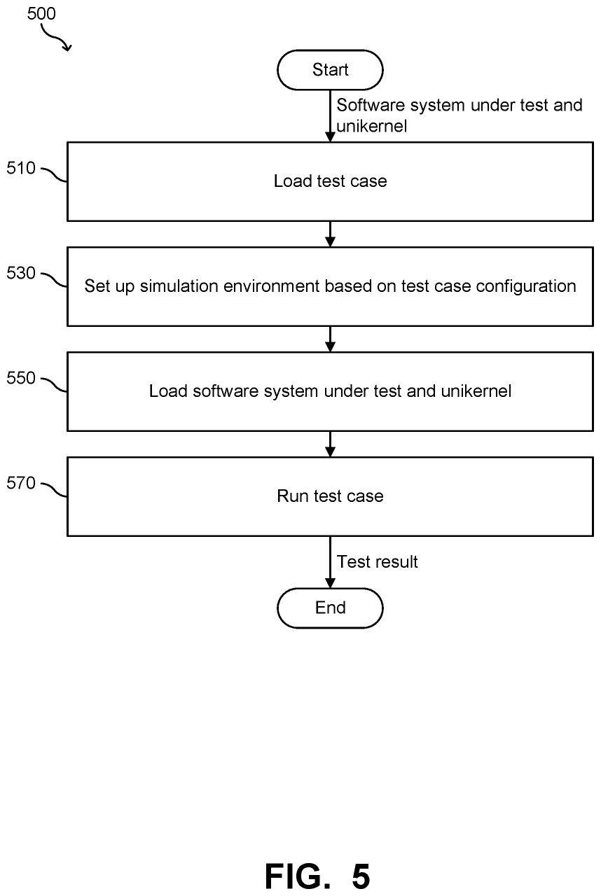

FIG. 5 is a flowchart depicting a method 500 for performing verification of a software system under test, according to one embodiment of the present disclosure. At 510, the test automation service 480 loads a test case from a suite of tests to be run to perform verification of the software system under test.

At 530, the test automation service 480 sets up the simulation environment based on test case configuration. For example, in a case where the software system under test is an ADAS system and the test case relates to testing operation of the ADAS system under particular driving conditions, the test automation service 480 may configure the simulation environment to initialize a three-dimensional physics simulation of driving conditions specified by the test case (e.g., approaching an intersection with a four-way stop sign, with two other vehicles approaching the same intersection from other directions).

At 550, the test automation service 480 loads the software system under test and the unikernel according to embodiments of the present disclosure, such as by running a compiled binary executable file containing the compiled unikernel 410 and the software system under test 430.

At 570, the test automation service 480 runs the test case, which may include, for example, updating the state of the simulation environment 440 based on a simulated clock in synchrony with updating or driving the virtual timer within the software system under test 430 (e.g., the virtual timer is synchronized with the simulated clock of the simulation environment), such that the simulation time matches the virtual time seen by the system under test. Running the test case produces a test result, such as whether the software system under test 430 passed the test case (a pass result or a fail result) and logs or other output regarding the running of test case (e.g., stack traces or core dumps in the case of failures, logs, and the like). While running the test case, various inputs may be provided to the software system under test 430 from the simulation environment 440 to the software system under test 430 through the simulator backend 414. For example, the sensor models 453 and environment models 470 may generate simulated radar data (corresponding to the data that a real ADAS system would receive from a radar sensor) that is transmitted to the software system under test 430 through the virtual hardware bus model of the simulator backend and supplied through the virtual hardware bus of the unikernel 410. The software system under test 430 generates outputs (e.g., steering outputs), which take the form of messages transmitted through the virtual hardware bus to the simulation environment and to change the state of the simulation environment (e.g., generate outputs to the virtual vehicle, which may change its steering direction based on outputs from the software system under test, and where the three-dimensional (3-D) model of the simulated environment is updated based on the speed of the vehicle and the updated steering direction of the vehicle in accordance with the vehicle dynamics models 451).

In some embodiments of the present disclosure, the test case may further specify that a fault (such as an out of memory error) is to be injected into the software system under test during the test process. For example, the test case may specify that any attempts to allocate memory will cause an out of memory error to be generated by the fault generation component 258 and injected into the system under test 230 by the fault injection component 218 of the unikernel 200. The operation of the system under test 430 will still be monitored to ensure that the system under test 430 operates as expected, even in the case of an injected fault.

Accordingly, the behavior of the system under test 430 under simulated timing conditions can be observed by the test automation system and to verify that the software system under test operates according to specifications. (In this example, verifying that the ADAS system under test correctly navigates through the intersection without colliding with the other vehicles and while also complying expected behavior among human motorists, such as rules regarding right of way for passing through the intersection and waiting for pedestrians to cross.)

In some experiments, using a unikernel approach according to embodiments of the present disclosure, a customized unikernel operating system image that is customized to the applications and middleware of the system under test can be built (e.g., compiled) in less than one minute and integrated into ECU simulations with a memory footprint under 10 megabytes (MB) and boot times in the millisecond range. For comparison, approaches using different operating system images running in a hypervisor were also tested against an embodiment according to the present disclosure. Approaches according to embodiments of the present disclosure are approximately an order of magnitude smaller in memory footprint and an order of magnitude faster in terms of boot time than the three comparative examples. This enables application/middleware validation and verification by providing the same workflow and environment that engineers are accustomed to using through the vehicle development platform, significantly lowers the simulation and infrastructure costs (e.g., storage, energy consumption, licenses), allows faster feedback loops, and thus shortens development cycles.

Accordingly, embodiments of the present disclosure relate to an ECU simulation using a POSIX®-based unikernel that provides significant advantages compared to a Linux®-based approach. Using a POSIX®-based unikernel according to embodiments of the present disclosure is more resource-efficient (e.g., has lower overhead) than a Linux®-based approach because embodiments of the present disclosure implement a unikernel that includes only the minimum functionalities required by the application and middleware of the system under test and by not requiring a hypervisor to develop ECU SW stacks. In a concrete study the unikernel shows a boot time that is forty times faster and an image footprint that is ten times smaller compared to an example Linux® operating system running in a hypervisor.

While aspects of embodiments of the present disclosure are described herein in the context of the automotive industry and ECUs, the present disclosure is not limited thereto and may also be applied to other embedded devices, such as in the Internet-of-Things (IoT) industry and other technologies that may make use of standardized operating systems (e.g., POSIX® operating systems).

According to one embodiment of the present disclosure, a method includes: receiving a software system under test including a software application; determining one or more operating system application programming interfaces invoked by the software system under test; compiling, by a processing device, a simulated operating system including a reduced interface layer providing services associated with the one or more operating system application programming interfaces that are invoked by the software system under test, the services including a virtual timer; and outputting the simulated operating system configured to execute the software system under test.

The method may further include: verifying the software system under test, including executing the software system under test on the simulated operating system in a verification system configured to supply test cases to the software system under test and configured to drive the virtual timer, wherein the one or more operating system application programming interfaces may include interactions with a hardware device, and wherein the simulated operating system may include a service associated with a virtual hardware device simulating the hardware device in the verification system.

The verifying the software system under test may include writing output from the software system under test to the virtual hardware device via the service associated with the virtual hardware device.

The verifying the software system under test may include reading input from the virtual hardware device to the software system under test via the service associated with the virtual hardware device.

The hardware device may be a network interface.

The verifying the software system under test may include: injecting an operating system fault from the verification system into the simulated operating system, and presenting the operating system fault to the software system under test via the reduced interface layer.

The method operating system fault may be selected from one or more of: an out of memory fault; a system reboot fault; and a connection timeout fault.

According to one embodiment of the present disclosure, a system includes: a memory storing instructions; and a processor, coupled with the memory and to execute the instructions, the instructions when executed cause the processor to: execute a simulator backend to provide a virtual hardware model of a simulated environment; and execute a software system under test on a simulated operating system kernel, the simulated operating system kernel being configured to provide an operating system feature for the software system under test to communicate with the virtual hardware model of the simulator backend, wherein the virtual hardware model includes a virtual timer.

The memory may further store instructions, which when executed by the processor, causes the processor to run a test case to verify the software system under test including setting conditions in the simulated environment in accordance with the test case, wherein the processor executes the simulator backend to increment the virtual timer in synchrony with a simulation clock of a simulation environment maintained by the simulator backend, wherein the processor executes the simulator backend to provide inputs from the simulation environment to the software system under test via the virtual hardware model, and wherein the processor executes the simulator backend to receive outputs from the software system under test via the virtual hardware model and provide the outputs to the simulation environment.

The simulation environment may include a simulated vehicle simulated by a three-dimensional physics engine.

The simulator backend may include a fault generation component configured to supply an operating system fault to a fault injection component of the simulated operating system kernel.

The simulator backend may include a logging and tracing component configured to log data recorded by a logging and tracing component of the simulated operating system kernel.

The processor may be configured to increment the virtual timer in synchrony with an update of a simulated clock of the simulation environment.

According to one embodiment of the present disclosure, a non-transitory computer-readable medium including stored instructions which, when executed by a processing device, cause the processing device to: receive a software system under test including a software application; determine one or more operating system application programming interfaces invoked by the software system under test; compile a simulated operating system including a reduced interface layer providing services associated with the one or more operating system application programming interfaces that are invoked by the software system under test; and output the simulated operating system configured to execute the software system under test.

The non-transitory computer-readable medium may further include stored instructions which, when executed by the processing device, cause the processing device to: configure a simulation environment in accordance with the test case; execute the software system under test on the simulated operating system; supplying a test case to the software system under test, including supplying inputs to the software system under test via the reduced interface layer of the simulated operating system based on a state of the simulation environment; monitor an output of the software system under test; and receive the output from the software system under test to the simulation environment via the reduced interface layer of the simulated operating system.

The reduced interface layer provides a virtual timer service to the software system under test based on a virtual timer of the simulated operating system, and the virtual timer may be incremented in synchrony with a simulation clock of the simulation environment.

The simulation environment may include a simulated vehicle simulated by a three-dimensional physics engine.

The simulated operating system may include a fault injection component, and supplying a test case to the software system under test may include injecting an operating system fault into the simulated operating system, the operating system fault being presented to the software system under test via the reduced interface layer.

The operating system fault may be selected from one or more of: an out of memory fault; a system reboot fault; and a connection timeout fault.

The simulated operating system may include a logging and tracing component configured to log operations performed by the software system under test.

FIG. 6 illustrates an example machine of a computer system 600 within which a set of instructions, for causing the machine to perform any one or more of the methodologies discussed herein, may be executed. In alternative implementations, the machine may be connected (e.g., networked) to other machines in a LAN, an intranet, an extranet, and/or the Internet. The machine may operate in the capacity of a server or a client machine in client-server network environment, as a peer machine in a peer-to-peer (or distributed) network environment, or as a server or a client machine in a cloud computing infrastructure or environment.

The machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random-access memory (DRAM) such as synchronous DRAM (SDRAM), a static memory 606 (e.g., flash memory, static random access memory (SRAM), etc.), and a data storage device 618, which communicate with each other via a bus 630.

Processing device 602 represents one or more processors such as a microprocessor, a central processing unit, or the like. More particularly, the processing device may be complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 602 may also be one or more special-purpose processing devices such as an application specific integrated circuit (ASIC), a field programmable gate array (FPGA), a digital signal processor (DSP), network processor, or the like. The processing device 602 may be configured to execute instructions 626 for performing the operations and steps described herein.

The computer system 600 may further include a network interface device 608 to communicate over the network 620. The computer system 600 also may include a video display unit 610 (e.g., a liquid crystal display (LCD) or a cathode ray tube (CRT)), an alphanumeric input device 612 (e.g., a keyboard), a cursor control device 614 (e.g., a mouse), a graphics processing unit 622, a signal generation device 616 (e.g., a speaker), graphics processing unit 622, video processing unit 628, and audio processing unit 632.

The data storage device 618 may include a machine-readable storage medium 624 (also known as a non-transitory computer-readable medium) on which is stored one or more sets of instructions 626 or software embodying any one or more of the methodologies or functions described herein. The instructions 626 may also reside, completely or at least partially, within the main memory 604 and/or within the processing device 602 during execution thereof by the computer system 600, the main memory 604 and the processing device 602 also constituting machine-readable storage media.

In some implementations, the instructions 626 include instructions to implement functionality corresponding to the present disclosure. While the machine-readable storage medium 624 is shown in an example implementation to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine and the processing device 602 to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm may be a sequence of operations leading to a desired result. The operations are those requiring physical manipulations of physical quantities. Such quantities may take the form of electrical or magnetic signals capable of being stored, combined, compared, and otherwise manipulated. Such signals may be referred to as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the present disclosure, it is appreciated that throughout the description, certain terms refer to the action and processes of a computer system, or similar electronic computing device, that manipulates and transforms data represented as physical (electronic) quantities within the computer system's registers and memories into other data similarly represented as physical quantities within the computer system memories or registers or other such information storage devices.

The present disclosure also relates to an apparatus for performing the operations herein. This apparatus may be specially constructed for the intended purposes, or it may include a computer selectively activated or reconfigured by a computer program stored in the computer. Such a computer program may be stored in a computer-readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various other systems may be used with programs in accordance with the teachings herein, or it may prove convenient to construct a more specialized apparatus to perform the method. In addition, the present disclosure is not described with reference to any particular programming language. It will be appreciated that a variety of programming languages may be used to implement the teachings of the disclosure as described herein.

The present disclosure may be provided as a computer program product, or software, that may include a machine-readable medium having stored thereon instructions, which may be used to program a computer system (or other electronic devices) to perform a process according to the present disclosure. A machine-readable medium includes any mechanism for storing information in a form readable by a machine (e.g., a computer). For example, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing disclosure, implementations of the disclosure have been described with reference to specific example implementations thereof. It will be evident that various modifications may be made thereto without departing from the broader spirit and scope of implementations of the disclosure as set forth in the following claims. Where the disclosure refers to some elements in the singular tense, more than one element can be depicted in the figures and like elements are labeled with like numerals. The disclosure and drawings are, accordingly, to be regarded in an illustrative sense rather than a restrictive sense.

What is claimed is:

1. A method comprising:
receiving a software system under test comprising a software application;
determining one or more operating system application programming interfaces invoked by the software system under test;
compiling, by a processing device, a simulated operating system comprising a reduced interface layer providing services associated with the one or more operating system application programming interfaces that are invoked by the software system under test, the services comprising a virtual timer; and
outputting the simulated operating system configured to execute the software system under test.

2. The method of claim 1, further comprising verifying the software system under test, comprising executing the software system under test on the simulated operating system in a verification system configured to supply test cases to the software system under test and configured to drive the virtual timer,
wherein the one or more operating system application programming interfaces comprise interactions with a hardware device, and
wherein the simulated operating system comprises a service associated with a virtual hardware device simulating the hardware device in the verification system.

3. The method of claim 2, wherein the verifying the software system under test comprises writing output from the software system under test to the virtual hardware device via the service associated with the virtual hardware device.

4. The method of claim 2, wherein the verifying the software system under test comprises reading input from the virtual hardware device to the software system under test via the service associated with the virtual hardware device.

5. The method of claim 2, wherein the hardware device is a network interface.

6. The method of claim 2, wherein the verifying the software system under test comprises:
injecting an operating system fault from the verification system into the simulated operating system, and
presenting the operating system fault to the software system under test via the reduced interface layer.

7. The method of claim 6, wherein the operating system fault is selected from one or more of:
an out of memory fault;
a system reboot fault; and
a connection timeout fault.

8. A system comprising:
a memory storing instructions; and
a processor, coupled with the memory and to execute the instructions, the instructions when executed cause the processor to:
execute a simulator backend to provide a virtual hardware model of a simulated environment; and
execute a software system under test on a simulated operating system kernel, the simulated operating system kernel being configured to provide an operating system feature for the software system under test to communicate with the virtual hardware model of the simulator backend, wherein the virtual hardware model comprises a virtual timer.

9. The system of claim 8, wherein the memory further stores instructions, which when executed by the processor, causes the processor to run a test case to verify the software system under test including setting conditions in the simulated environment in accordance with the test case,
wherein the processor executes the simulator backend to increment the virtual timer in synchrony with a simulation clock of a simulation environment maintained by the simulator backend,
wherein the processor executes the simulator backend to provide inputs from the simulation environment to the software system under test via the virtual hardware model, and
wherein the processor executes the simulator backend to receive outputs from the software system under test via the virtual hardware model and provide the outputs to the simulation environment.

10. The system of claim 9, wherein the simulation environment comprises a simulated vehicle simulated by a three-dimensional physics engine.

11. The system of claim 8, wherein the simulator backend comprises a fault generation component configured to supply an operating system fault to a fault injection component of the simulated operating system kernel.

12. The system of claim 8, wherein the simulator backend comprises a logging and tracing component configured to log data recorded by a logging and tracing component of the simulated operating system kernel.

13. The system of claim 8, wherein the processor is configured to increment the virtual timer in synchrony with an update of a simulated clock of the simulation environment.

14. A non-transitory computer-readable medium comprising stored instructions which, when executed by a processing device, cause the processing device to:
receive a software system under test comprising a software application;
determine one or more operating system application programming interfaces invoked by the software system under test;
compile a simulated operating system comprising a reduced interface layer providing services associated with the one or more operating system application programming interfaces that are invoked by the software system under test; and
output the simulated operating system configured to execute the software system under test.

15. The non-transitory computer-readable medium of claim 14, further comprising stored instructions which, when executed by the processing device, cause the processing device to:
configure a simulation environment in accordance with the test case;
execute the software system under test on the simulated operating system;
supplying a test case to the software system under test, comprising supplying inputs to the software system under test via the reduced interface layer of the simulated operating system based on a state of the simulation environment;
monitor an output of the software system under test; and
receive the output from the software system under test to the simulation environment via the reduced interface layer of the simulated operating system.

16. The non-transitory computer-readable medium of claim 15, wherein the reduced interface layer provides a virtual timer service to the software system under test based on a virtual timer of the simulated operating system, and
wherein the virtual timer is incremented in synchrony with a simulation clock of the simulation environment.

17. The non-transitory computer-readable medium of claim 15, wherein the simulation environment comprises a simulated vehicle simulated by a three-dimensional physics engine.

18. The non-transitory computer-readable medium of claim 14, wherein the simulated operating system comprises a fault injection component, and
wherein supplying a test case to the software system under test comprises injecting an operating system fault into the simulated operating system, the operating system fault being presented to the software system under test via the reduced interface layer.

19. The non-transitory computer-readable medium of claim 18, wherein the operating system fault is selected from one or more of:
an out of memory fault;
a system reboot fault; and
a connection timeout fault.

20. The non-transitory computer-readable medium of claim 14, wherein the simulated operating system comprises a logging and tracing component configured to log operations performed by the software system under test.
